(19) United States
(12) Patent Application Publication
(10) Pub. No.: US 2026/0011682 A1
(43) Pub. Date: Jan. 8, 2026

(54) HYBRID BONDING OF SEMICONDUCTOR CMOS WAFER AND SEMICONDUCTOR MEMORY ARRAY WAFER USING DEBONDABLE CARRIERS

(71) Applicant: Micron Technology, Inc., Boise, ID (US)

(72) Inventors: Kunal R. Parekh, Boise, ID (US); Andrew M. Bayless, Boise, ID (US); Kyle K. Kirby, Eagle, ID (US)

(21) Appl. No.: 19/257,845

(22) Filed: Jul. 2, 2025

Related U.S. Application Data
(60) Provisional application No. 63/668,158, filed on Jul. 5, 2024.

(51) Int. Cl. H01L 23/00

(52) U.S. Cl. CPC H01L 24/80; H01L 24/08; H01L 2224/08145; H01L 2224/80006; H01L 2224/80895; H01L 2224/80896

(57) ABSTRACT

The present technology relates to hybrid bonding of semiconductor memory wafer and semiconductor CMOS wafer using one or more debondable carriers. In one embodiment, a semiconductor device assembly is disclosed. The semiconductor device assembly includes a first semiconductor wafer having complementary metal-oxide-semiconductor (CMOS) transistor devices, the first semiconductor wafer having a first frontside surface and a first backside surface, and a second semiconductor wafer having one or more memory arrays, the second semiconductor wafer having a second frontside surface and a second backside surface, wherein a bonding interface is formed between the first backside surface of the first semiconductor wafer and the second frontside surface of the second semiconductor wafer, and wherein the first semiconductor wafer has a first dielectric layer disposed on its first frontside surface.

### CROSS-REFERENCE TO RELATED APPLICATION(S)

The present application claims priority to U.S. Provisional Patent Application No. 63/668,158, filed Jul. 5, 2024, the disclosure of which is incorporated herein by reference in its entirety.

### TECHNICAL FIELD

The present disclosure generally relates to semiconductor wafer bonding and debonding processes, and more particularly relates to hybrid bonding of semiconductor memory wafer and semiconductor CMOS wafer using one or more debondable carriers.

### BACKGROUND

Semiconductor wafers bonding and debonding are foundational technologies in modern semiconductor fabrication, enabling the creation of advanced semiconductor assembly and devices with improved performance, reduced size, and new functionalities. During a wafer bonding process, two or more semiconductor wafers are joined together using various bonding techniques such as fusion bonding, adhesive bonding, and others. Debonding is a process of separating bonded wafers after necessary processing has been completed. Various techniques including mechanical debonding, thermal slide debonding, and laser debonding can be adopted to physically separate the wafers. Often times the wafer debonding process can be challenging, especially in temporary bonding applications where a carrier wafer needs to be removed.

### BRIEF DESCRIPTION OF THE DRAWINGS

FIGS. 1A to 1C are schematic and cross-sectional side views of a carrier wafer during processes of fabricating a “dielectric layer-debond layer-dielectric layer” stack structure on the carrier wafer in accordance with various embodiments of the present technology.

FIGS. 2A to 2C are schematic and cross-sectional side views of another carrier wafer during processes of fabricating a “dielectric layer-debond layer-dielectric layer” stack structure on the carrier wafer in accordance with various embodiments of the present technology.

FIGS. 3A to 3H are schematic and cross-sectional side views of semiconductor wafers during semiconductor wafers face-to-back (F2B) bonding and debonding processes in accordance with various embodiments of the present technology.

FIGS. 4A to 4F are schematic and cross-sectional side views of semiconductor wafers during semiconductor wafers face-to-face (F2F) bonding and debonding processes in accordance with various embodiments of the present technology.

FIGS. 5A to 5D are schematic and cross-sectional side views of stacked semiconductor memory wafers F2F bonded to a semiconductor CMOS wafer in accordance with various embodiments of the present technology.

FIG. 6 is a flow chart illustrating a method for bonding and debonding semiconductor wafers in accordance with various embodiments of the present technology.

FIG. 7 is a partially schematic block diagram of a system that includes a semiconductor device configured in accordance with various embodiments of the present technology.

### DETAILED DESCRIPTION

Semiconductor wafer bonding and debonding are critical steps in the fabrication of semiconductor devices, especially for those utilizing thin wafers and advanced packaging technologies such as DRAM, NAND flash, and high-bandwidth memory (HBM). In particular, semiconductor wafer debonding process presents challenges that can impact manufacturing yield, device performance, and reliability. For example, the expansion coefficients of different materials on the bonded semiconductor wafers can vary, leading to thermal stress during the heating and cooling phases. The thermal stress contained in the bonded wafers can also cause warping, cracking, or delamination of the materials when separating the wafers. In addition, applying mechanical force to separate the bonded wafers can lead to breakage or induce micro-cracks in the wafers, particularly for very thin wafers. Ensuring uniform force application without damaging the wafer is a significant challenge. Further, certain wafer bonding process may form a strong bonding interface (e.g., with chemical bonds having a high bond energy) between the bonded wafers, making the downstream wafer debonding process extremely hard.

For advanced memory device fabrication, stacking memory array wafers with one or more CMOS wafers presents unique wafer debonding challenges, because this process can be critical for creating high-performance integrated memory devices. Additional memory device fabrication challenges arise from the need to maintain the integrity and functionality of both the memory array wafers and the underlying CMOS circuitries throughout the wafer bonding and debonding processes.

To solve the issues and challenges described above, the present technology provides a hybrid wafer bonding scheme utilizing a debondable carrier wafer. The bonded semiconductor wafers include a semiconductor wafer having CMOS devices and another semiconductor wafer having memory arrays. In one embodiment, a frontside surface of the semiconductor memory array wafer is bonded to a backside surface of the CMOS semiconductor wafer. Additionally, the CMOS semiconductor wafer can be thinned using a mechanical polishing process or a cleave process (e.g., a micro-cleave process, a nano-cleave process, or a precise cleave process) along with ion implantation. In this example, a single carrier wafer having a stack “dielectric layer-debond layer-dielectric layer” structure can be utilized in assisting above noted F2B hybrid wafer bonding scheme and can be further debonded from the final device. Alternatively, the present technology can be adopted in forming a F2F bonding of semiconductor memory wafer and CMOS semiconductor wafer. In this embodiment, a single crystal silicon layer or a silicon wafer can be formed above the single carrier wafer having the stack “dielectric layer-debond layer-dielectric layer” structure. Particularly, CMOS devices can be fabricated on a frontside surface of the thinned single crystal silicon layer. Hybrid bonding process can be used for bonding of a frontside surface of the semiconductor memory wafer with a frontside surface of the thinned single crystal silicon layer with CMOS devices. The final semiconductor device includes a F2F bonding interface between the semiconductor memory layer and the CMOS semiconductor layer, within which the carrier wafer substrate can be debonded/removed.

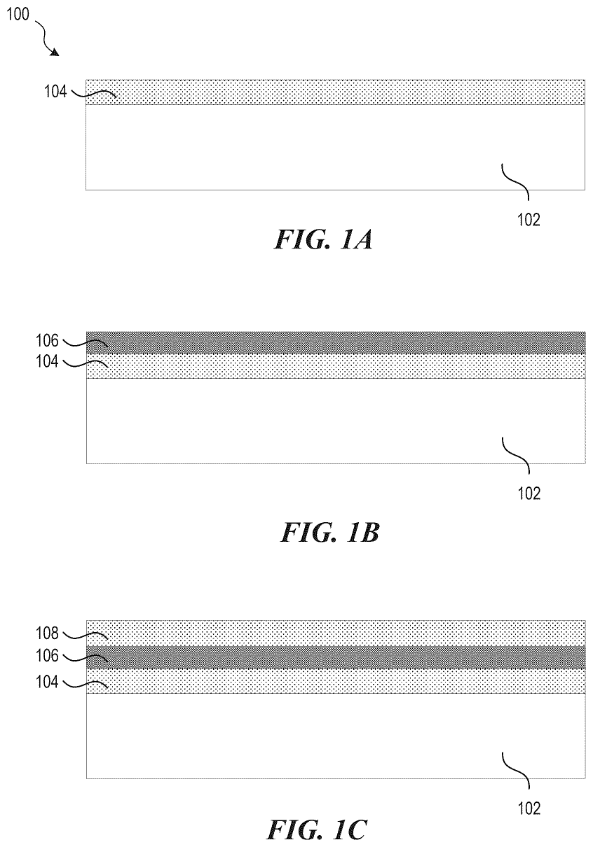

Various carrier wafers can be utilized for the wafer bonding processes included in the present technology. For example, FIGS. 1A to 1C are schematic and cross-sectional side views of a carrier wafer 100 during processes of fabricating a “dielectric layer-debond layer-dielectric layer” stack structure on the carrier wafer 100 in accordance with various embodiments of the present technology. As shown in FIG. 1A, a dielectric layer 104 can be deposited above a frontside surface of a semiconductor substrate 102. The semiconductor substrate 102 can be made of materials including silicon, germanium, gallium arsenide, silicon carbide, sapphire, indium phosphide. The continuously coated dielectric layer 104 can be made of materials including silicon oxide (SiO), silicon nitride (SIN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Specifically, thin film deposition techniques such as chemical vapor deposition (CVD), physical vapor deposition (PVD), and/or atomic layer deposition (ALD) processes can be used to fabricate the dielectric layer 104. Here, the dielectric layer 104 may have a thickness ranging up to 5 μm.

In a next step, a metal layer 106 can be deposited on a frontside surface of the dielectric layer 104, as shown in FIG. 1B. Thin film deposition techniques such as CVD technique, PVD technique, and/or ALD technique can be used to fabricate the metal layer 106. Here, the metal layer 106 can be made of metallic materials including nickel, aluminum, titanium, copper, gold, and/or their alloy compound. In particular, the metal layer 106 can have a thickness up to 150 nm.

Once the metal layer 106 is deposited, another dielectric layer 108 can be deposited on a frontside surface of the metal layer 106, as shown in FIG. 1C. Similar to the dielectric layer 104, the dielectric layer 108 can be deposited utilizing thin film deposition techniques such as CVD technique, PVD technique, and/or ALD technique. The dielectric layer 108 can be made of materials including SiO, SiN, SiBCN, SIOCN, SiOC, SiCN, SiBN, a low-k dielectric material, or a combination thereof. In this example, the dielectric layers 108 and 104 can be made a same type of material. In some other examples, the dielectric layers 108 and 104 can be made of different materials. Here, the dielectric layer 108 may have a thickness up to 150 nm. In this example, the carrier wafer 100 includes a “dielectric layer 108—debond layer 106—dielectric layer 104” stack structure of which the debond layer is the metal layer 106. A wafer debonding process such as chemical assisted debonding process or a mechanical debonding process can be conducted, e.g., crossing the metal layer 106 of the carrier wafer 100, in a downstream fabrication process to separate the semiconductor substrate 102 and other semiconductor wafers bonded thereon.

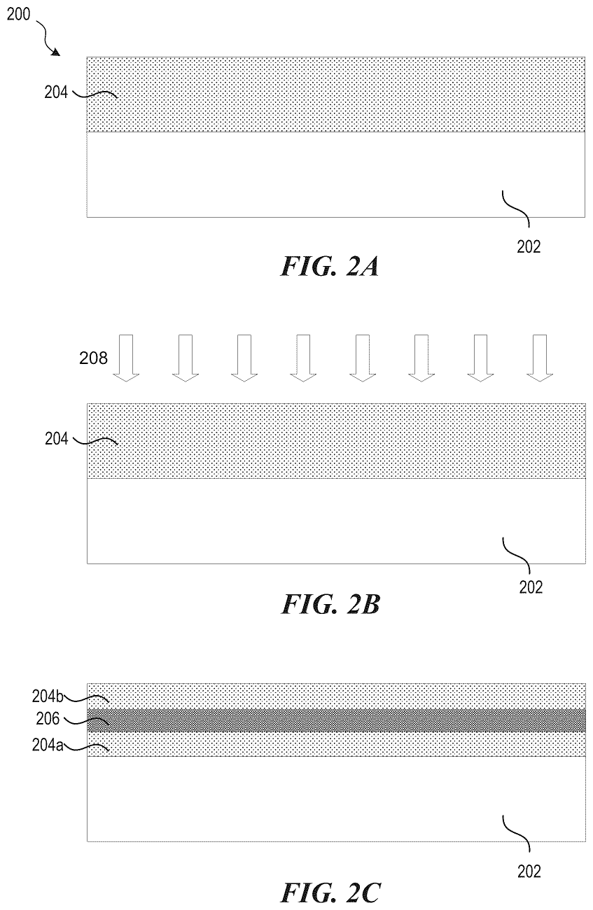

FIGS. 2A to 2C are schematic and cross-sectional side views of another carrier wafer 200 during processes of fabricating the “dielectric layer-debond layer-dielectric layer” stack structure on the carrier wafer 200 in accordance with various embodiments of the present technology. In this example, the debond layer contains inert ions and is configured for wafer debonding using a cleave process (e.g., a micro-cleave process, a nano-cleave process, or a precise cleave process). As shown in FIG. 2A, the process starts from depositing a dielectric layer 204 on a frontside surface of the semiconductor substrate 202. The dielectric layer is continuously deposited and has a thickness ranging up to 10 μm. Similar to the dielectric layer 104, the dielectric layer 204 can be deposited utilizing thin film deposition techniques such as CVD technique, PVD technique, and/or ALD technique. The dielectric layer 204 can be made of materials including SiO, SiN, SiBCN, SiOCN, SiOC, SICN, SiBN, a low-k dielectric material, or a combination thereof.

In a next step, as shown in FIG. 2B, inert ions can be doped into the dielectric layer 204. For example, inert ions 208 can be implanted into the dielectric layer 204 through its frontside surface. Here, an ion implantation process can be conducted for doping inert ions such as argon (Ar). Ion implantation process conditions including ion energy, ion dose, implantation angle, implantation temperature, and implantation time can be adjusted to achieve various doping levels of the inert ions at different maximum doping regions in the dielectric layer 204. For example, an Ar ion beam with a lower acceleration voltage and a higher dose level can be implanted into the dielectric layer 204 through its frontside surface to form a local maximum doping region that is deeper in the dielectric layer 204. In comparison, another Ar ion beam with a larger acceleration voltage and a lower dose level can be implanted into a shallower region of the dielectric layer 204.

Here, the inert ions implantation process forms a peak doping layer 206 in the dielectric layer 204, as shown in FIG. 2C. The peak doping layer 206 may have a doping level ranging from 1×10¹⁵ ions·cm⁻² to 1×10²² ions·cm⁻². In this example, the peak doping layer 206 includes inert ions such as Hydrogen ion, Ar ion, Helium ion, Neon ion, Krypton ion, and/or Xenon ion. In some other examples, silicon ions can also be doped into the dielectric layer 204. The acceleration voltage of the ion implantation process ranges from 1KeV to 1 MeV. Additionally, the peak doping layer 206 may have a thickness ranging up to 150 nm and with a distance close to 5 μm from the frontside surface of the semiconductor substrate 202. In this example, the carrier wafer 200 includes a “dielectric layer 204b—debond layer 206—dielectric layer 204a” stack structure, of which the debond layer is the peak doping layer 206. A wafer debonding process such as a cleave process can be conducted, e.g., crossing the peak doping layer 206 of the carrier wafer 200, in a downstream fabrication process to separate the semiconductor substrate 202 and other semiconductor wafers bonded thereon.

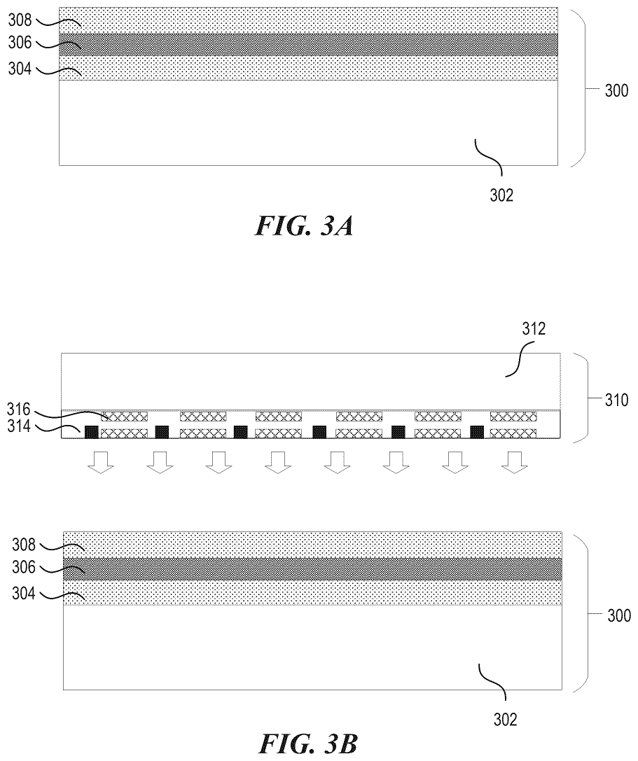

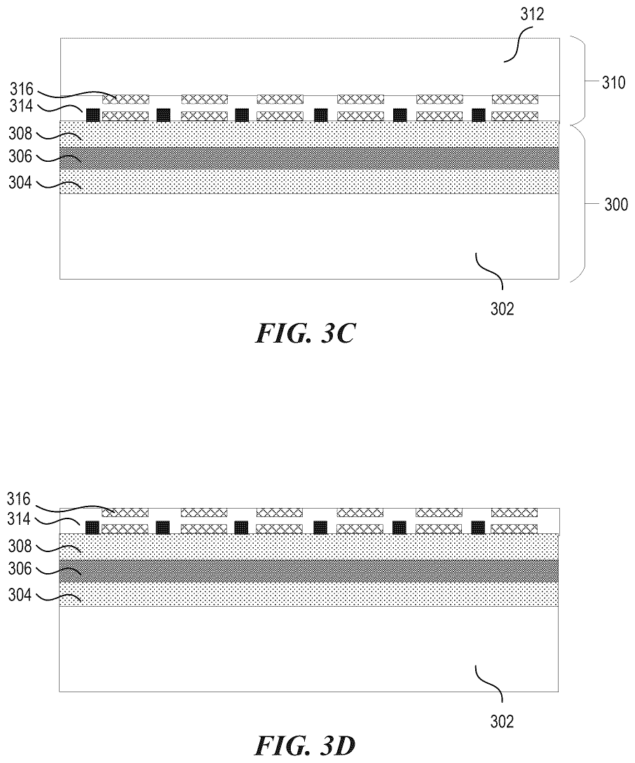

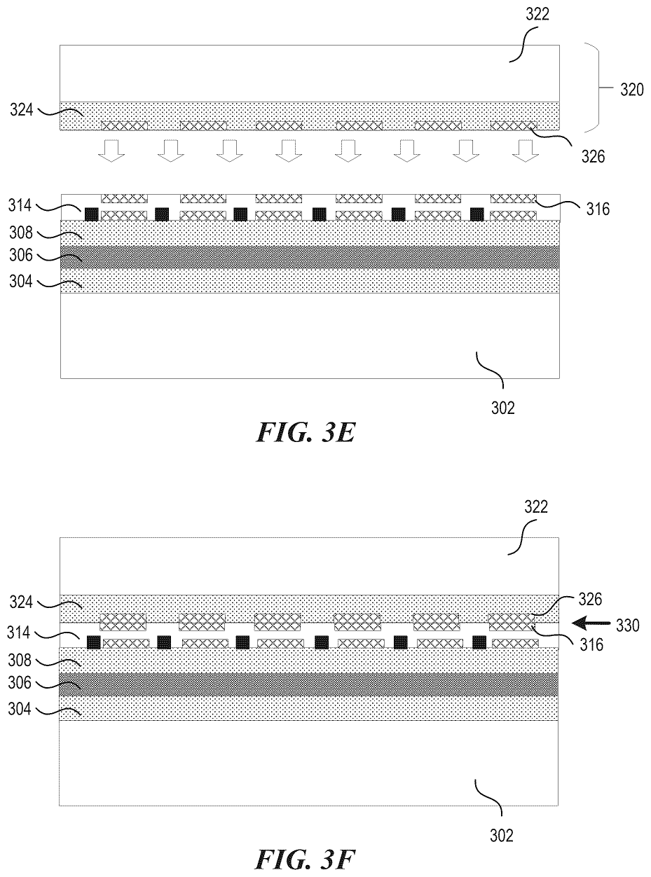

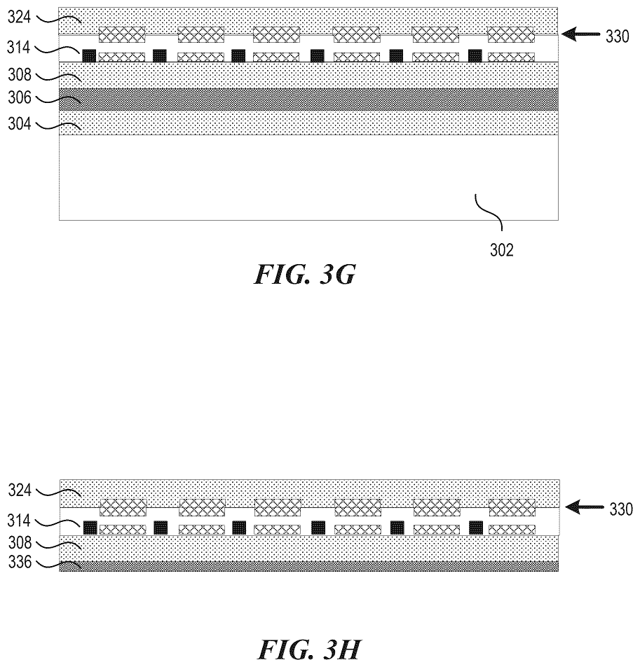

FIGS. 3A to 3H are schematic and cross-sectional side views of semiconductor wafers during semiconductor wafers F2B bonding and debonding processes in accordance with various embodiments of the present technology. In this example, a carrier wafer 300 having the “dielectric layer-debond layer-dielectric layer” stack structure is provided for the bonding and debonding processes. As shown in FIG. 3A, a dielectric layer 304, a debond layer 306, and a dielectric layer 308 are sequentially disposed above a frontside surface of a semiconductor substrate 302. The stack structure of “dielectric layer 308—debond layer 306—dielectric layer 304” can be similar to the one shown in FIGS. 1C and 2C. In particular, the debond layer 306 of this example can be made of metallic material and similar to the metal layer 106 of the carrier wafer 100. Alternatively, the debond layer 306 can included inert ions and be similar to the peak doping layer 206 of the carrier wafer 200.

In this example, a semiconductor wafer 310 having complementary metal-oxide-semiconductor (CMOS) transistor devices is provided for the wafer bonding process. As shown in FIG. 3B, the semiconductor wafer 310 includes a semiconductor layer 314 disposed on a substrate 312. The semiconductor layer 314 may also include semiconductor devices such as transistors, passive device components, electrical interconnections, as well as dielectrics isolating the devices included in the semiconductor layer 314. Specifically, the semiconductor layer 314 can include metal pads 316 on its frontside surface and backside surface. As shown, the semiconductor wafer 310 can be aligned to and have its frontside surface facing towards the frontside surface of the carrier wafer substrate 302.

The semiconductor wafer 310 can be bonded with the carrier wafer 300 using a hybrid bonding (also refers as fusion bonding or direct bonding) process. As shown in FIG. 3C, the frontside surface of the semiconductor layer 314 can be boned to the frontside surface of the dielectric layer 308. In this example, dielectric-dielectric bonds can be formed between the semiconductor layer 314 and the dielectric layer 308. During the bonding process, the semiconductor wafer 310 and carrier wafer 300 are brought into contact at room temperature or a slightly elevated temperature. The semiconductor wafer 310 and carrier wafer 300 can also be subjected to a combination of pressure and elevated temperature to strengthen the bond therebetween. After the initial bonding, the semiconductor wafer 310 and carrier wafer 300 can undergo an annealing process, e.g., at an annealing temperature close to 300° C. and for a period up to 10 minutes.

In a next step, the bonded semiconductor wafer 310 can be thinned on its backside. As shown in FIG. 3D, the substrate 312 of the semiconductor wafer can be removed from the backside surface of the semiconductor wafer 310. Here, a chemical mechanical planarization (CMP) process, a back grinding process, or a wet or dry etching process can be conducted on the backside surface of the substrate 312 for the thinning of the semiconductor wafer 310. In this example, the substrate 312 can be removed (or partially removed) from the bonded structure of semiconductor wafer 310 and carrier wafer 300. The wafer backside thinning process can expose the metal pads 316 disposed on the backside surface of the semiconductor layer 314.

Other semiconductor wafers can be further bonded to the semiconductor layer 314. For example, a semiconductor wafer 320 having one or more memory arrays can be provided into the process. As shown in FIG. 3E, the semiconductor wafer 320 includes a semiconductor layer 324 disposed on a substrate 322. The semiconductor layer 324 includes one or more memory arrays. In addition, the semiconductor layer 324 may include metal pads 326 on its frontside surface and dielectric isolating the one or more memory arrays and the metal pads 326. In this example, the semiconductor wafer 320 is aligned to and have its frontside surface, i.e., the frontside surface of the semiconductor layer 324, facing towards the backside surface of the semiconductor layer 314.

FIG. 3F shows the semiconductor wafer 320 bonded on the semiconductor layer 314 and the carrier wafer 300. A hybrid wafer bonding process can be used to form dielectric-dielectric bonds and metal-metal bonds at the bonding interface 330 between the frontside surface of semiconductor layer 324 and the backside surface of the semiconductor layer 314. As shown, corresponding metal pads 316 and 326 can be aligned and bonded together to form metal-metal bonds at the bonding interface 330. After an initial contact between the semiconductor layers 314 and 324, an annealing process can be conducted for the hybrid bonding to heat up the processing temperature, e.g., to close to 300° C. under a controlled atmosphere for a period of time. The annealing process enhances not only the metal-metal bonding by promoting metal interdiffusion but also the dielectric-dielectric bonding by promoting dielectric material interdiffusion, at the F2B bonding interface 330.

In a next step, a wafer backside thinning process can be conducted on the substrate 322 of the semiconductor wafer 320. As shown in FIG. 3G, the substrate 322 of the semiconductor wafer 320 can be thinned or removed from the backside surface of the semiconductor wafer 320. Here, a CMP process, a back grinding process, or a wet or dry etching process can be conducted on the backside surface of the substrate 322 for the wafer backside thinning. Here, the substrate 322 can be removed (or partially removed) from the bonded structure of semiconductor wafer 320, semiconductor layer 314 and carrier wafer 300. The wafer backside thinning process can expose the dielectrics of the semiconductor layer 324. In some other examples, an ion implantation process and a cleave process can be conducted to etch off the substrate 322 from the semiconductor wafer 320. For example, inert ions such as Ar ions can be implanted into the substrate 322. A cleave process can be conducted from the edge of the semiconductor wafer 320, e.g., crossing a cleavage plane of a peak inert ion region of the substrate 322, to remove a major portion of the substrate 302 from its semiconductor layer 324. After the wafer backside thinning process, residual inert ions can be existed on the thinned backside surface of the semiconductor wafer 320.

In the present technology, the substrate 302 of the carrier wafer 300 can be debonded from the semiconductor layers 314 and 324. As shown in FIG. 3H, the substrate 302 can be debonded, alongside the dielectric layer 304 and across the debond layer 306. Various semiconductor wafer debond processes can be used here to debond the substrate 302. For debond layer 306 that is made of metallic materials, a wafer debonding process such as chemical assisted debonding process or a mechanical debonding process can be conducted crossing the metal layer 306 of the carrier wafer 300 to debond the substrate 302 from the semiconductor layers 314 and 324 bonded thereon. In another example, for debond layer 306 that contains inert ions, a cleave process can be conducted, e.g., crossing a cleavage plane disposed in the debond layer 306, to debond the substrate 302. Here, the implanted inert ions create weakness in the debond layer 306. In this debonding process, a mechanical or thermal stimulus can be applied to initiate the cleavage along the implanted cleavage plane of the debond layer 306, separating the bulk substrate 302 from semiconductor structure dispose there above. After the carrier wafer substrate is debonded, a residue debond layer 336 is formed on a backside surface of the dielectric layer 308. The residue debond layer 336 contains materials, e.g., metallic material or inert ions, that were originally exist in the debond layer 306.

After undergoing the carrier wafer substrate debond process, the debonded carrier wafer substrate 302 can be cleaned, inspected, and reused in other semiconductor wafer processing cycles. Depending on the material and condition of debonded carrier wafer substrate, the reuse of carrier wafer substrate helps in reducing manufacturing costs and minimizing waste. Alternatively, the debonded carrier wafer substrate 302 can be subjected to material recovery processes to recycle valuable or rare materials. In some examples, a CMP process can be performed on the debonded carrier wafer substrate 302 to prepare its surface.

The final semiconductor device assembly structure shown in FIG. 3H includes a semiconductor layer 324 having memory arrays and a semiconductor layer 314 having CMOS devices. The frontside surface of the semiconductor layer 324 is bonded to the backside surface of the semiconductor layer 314 and forms a F2B bonding interface 330. The semiconductor device assembly structure also includes the dielectric layer 308 and the residue debond layer 336 disposed on the frontside surface of the semiconductor layer 314. In some examples, the residue debond layer 336 can be further removed using a wet or dry chemical etching process. In some other examples, the dielectric layer 308 can be further removed by a selective etching process. In some other examples, the dielectric layer 308 can be removed by a CMP process (e.g., a buff CMP process) to prepare the surface of the semiconductor device assembly structure of FIG. 3H.

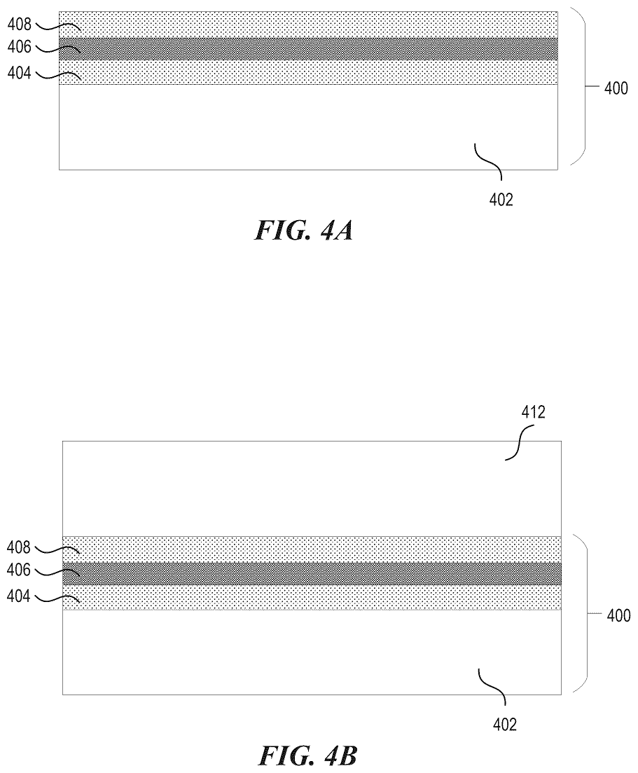

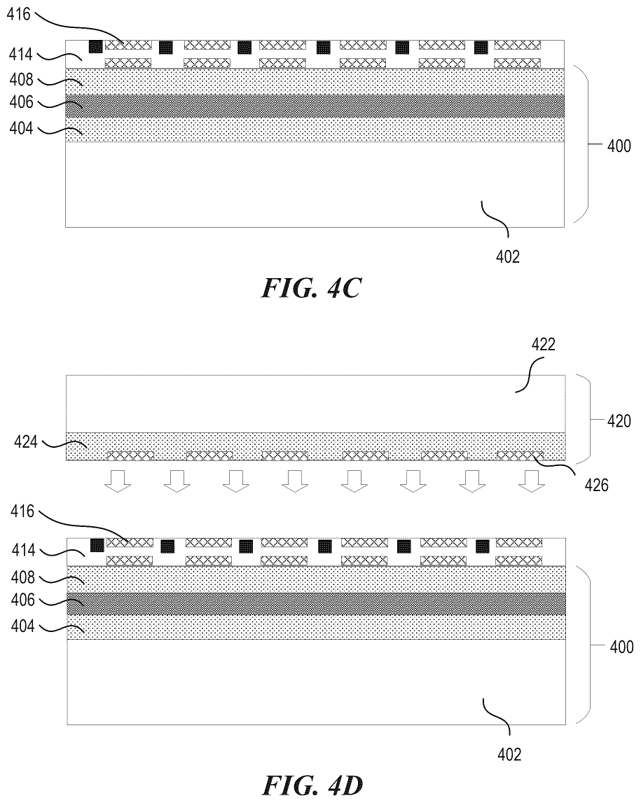

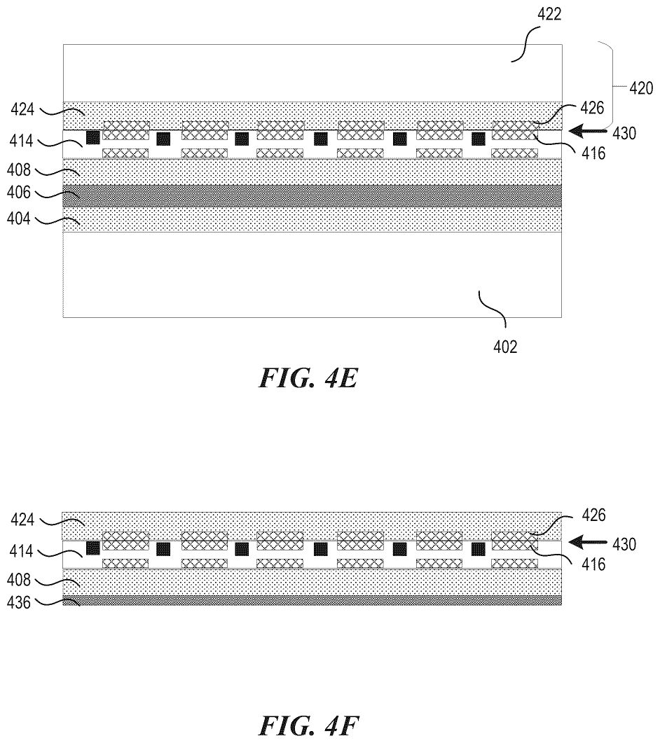

FIGS. 4A to 4F are schematic and cross-sectional side views of semiconductor wafers during semiconductor wafers F2F bonding and debonding processes in accordance with various embodiments of the present technology. In this example, a carrier wafer 400 having the “dielectric layer-debond layer-dielectric layer” stack structure can be provided for the bonding and debonding processes described herein. As shown in FIG. 4A, a dielectric layer 404, a debond layer 406, and a dielectric layer 408 can be sequentially disposed above a frontside surface of a semiconductor substrate 402. The stack structure of “dielectric layer 408—debond layer 406—dielectric layer 404” can be similar to the one shown in FIGS. 1C and 2C. In particular, the debond layer 406 of the carrier wafer 400 can be made of metallic material and similar to the metal layer 106 of the carrier wafer 100. Alternatively, the debond layer 406 can include inert ions and be similar to the peak doping layer 206 of the carrier wafer 200.

In a next step, a single crystal silicon layer 412 can be deposited above the frontside surface of the dielectric layer 408, as shown in FIG. 4B. Various types of thin film deposition processes such as a CVD process, or a Molecular Beam Epitaxy (MBE) process can be adopted here to fabricate the single crystal silicon layer 412. The single crystal silicon layer 412 may have a thickness ranging up to 500 μm.

FIG. 4C illustrates that semiconductor device fabrication processes can be further conducted on the single crystal silicon layer 412 to form a semiconductor layer 414. As shown, the semiconductor layer 414 is disposed on a frontside surface of the single crystal silicon layer 412 and includes CMOS transistor devices. In addition, the semiconductor layer 414 may include semiconductor devices such as transistors, passive device components, electrical interconnections, as well as dielectrics isolating the devices included in the semiconductor layer 414. Specifically, the semiconductor layer 414 can include metal pads 416 disposed on its frontside surface and backside surface. In this example, the single crystal silicon layer 412 can be firstly thinned down to a desired thickness, prior to the fabricating of semiconductor devices of the semiconductor layer 414. A CMP process or wafer grinding process can be adopted here to thin down the single crystal silicon layer 412.

One or more semiconductor wafers can be further bonded to the semiconductor layer 414. In this example, a semiconductor wafer 420 having one or more memory arrays can be provided into the process. As shown in FIG. 4D, the semiconductor wafer 420 includes a semiconductor layer 424 disposed on a substrate 422. The semiconductor layer 424 includes one or more memory arrays. In addition, the semiconductor layer 424 may include metal pads 426 on its frontside surface and dielectric isolating the one or more memory arrays and the metal pads 426. In this example, the semiconductor wafer 420 can be aligned to and have its frontside surface, i.e., the frontside surface of the semiconductor layer 424, facing towards the frontside surface of the semiconductor layer 414.

FIG. 4E shows the semiconductor wafer 420 bonded on the semiconductor layer 414 and the carrier wafer 400. A hybrid wafer bonding process can be used in this example to form dielectric-dielectric bonds and metal-metal bonds at the bonding interface 430 between the frontside surface of semiconductor layer 424 and the frontside surface of the semiconductor layer 414. As shown, corresponding metal pads 416 and 426 can be aligned and bonded together to form metal-metal bonds at the F2F bonding interface 430. After an initial contact between the semiconductor layers 414 and 424, an annealing process can be conducted for the hybrid bonding to heat up the processing temperature, e.g., to close to 300° C. under a controlled atmosphere for a period up to 30 minutes. The annealing process enhances the metal-metal bonds and the dielectric-dielectric bonds by promoting corresponding materials interdiffusion, at the F2F bonding interface 430.

In a next step, a wafer backside thinning process can be conducted on the substrate 422 of the semiconductor wafer 420. As shown in FIG. 4F, the substrate 422 of the semiconductor wafer 420 can be thinned or removed from the backside surface of the semiconductor wafer 420. Similar to the description of FIG. 3G, a CMP process, a back grinding process, or a wet or dry etching process can be conducted in this step on the backside surface of the substrate 422 for the wafer backside thinning process. In this example, the substrate 422 can be removed (or partially removed) from the bonded structure of semiconductor wafer 420, semiconductor layer 414, and carrier wafer 400. The wafer backside thinning process can expose the dielectrics of the semiconductor layer 424. In some other examples, an ion implantation process and/or a cleave process can be conducted on the substrate 422 to etch it off from the semiconductor wafer 420. For example, inert ions such as Ar ions can be implanted into the substrate 422. A cleave process can be conducted from the edge of the semiconductor wafer 420, e.g., crossing a cleavage plane of a peak inert ion region of the substrate 422, to remove a major portion of the substrate 402 off its semiconductor wafer 320. After the cleave process, residual inert ions exist on the thinned backside surface of the semiconductor wafer 420.

In the present technology, the substrate 402 of the carrier wafer 400 can be debonded from the bonded semiconductor layers 414 and 424. As shown in FIG. 4F, the substrate 402 can be deboned across the debond layer 406. Various semiconductor wafer debond processes can be used in the present technology to debond the substrate 402. For debond layer 406 that is made of metallic materials, a wafer debonding process such as chemical assisted debonding process or a mechanical debonding process can be conducted crossing the metal layer 406 of the carrier wafer 400 to debond the substrate 402 from the semiconductor layers 414 and 424 bonded thereon. In another example, for debond layer 306 that contains inert ions, a cleave process can be conducted, e.g., crossing a cleavage plane disposed in the debond layer 406, to debond the substrate 402. Here, the implanted inert ions weaken the debond layer 406. In this debonding process, a mechanical or thermal stimulus can be applied to initiate the cleavage along the implanted cleavage plane of the debond layer 406, separating the bulk substrate 402 from semiconductor structure dispose there above. After the carrier wafer substrate is debonded, a residue debond layer 436 is formed on a backside surface of the dielectric layer 408. The residue debond layer 436 contains materials, e.g., metallic material or inert ions, that were originally exist in the debond layer 406.

In this example, the final semiconductor device assembly structure shown in FIG. 4F includes a semiconductor layer 424 having memory arrays and a semiconductor layer 414 having CMOS devices. The frontside surface of the semiconductor layer 324 is bonded to the frontside surface of the semiconductor layer 314, and forms a F2F bonding interface 430. The semiconductor device assembly structure also includes the dielectric layer 408 and the residue debond layer 436 disposed on the backside surface of the semiconductor layer 514. In some examples, the residue debond layer 536 can be further removed using a wet or dry chemical etching process. In some other examples, the dielectric layer 308 can be further removed by a selective etching process.

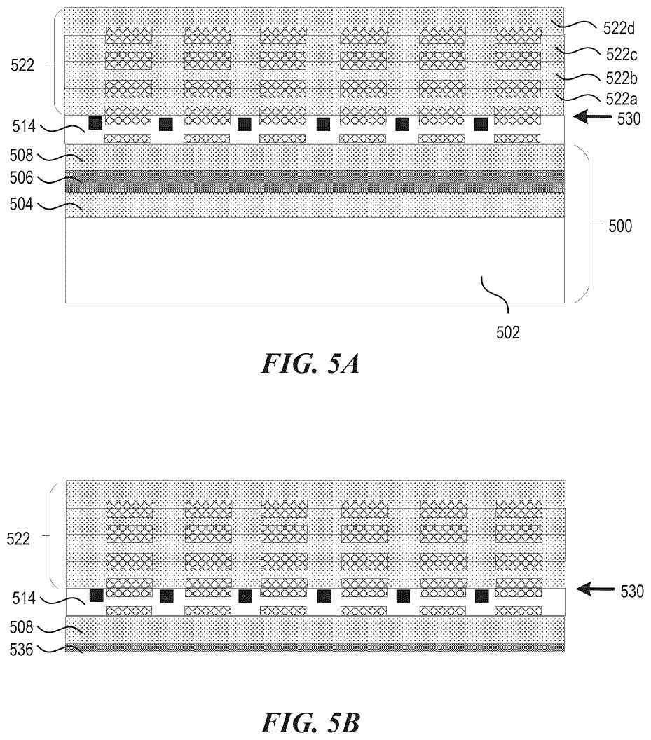

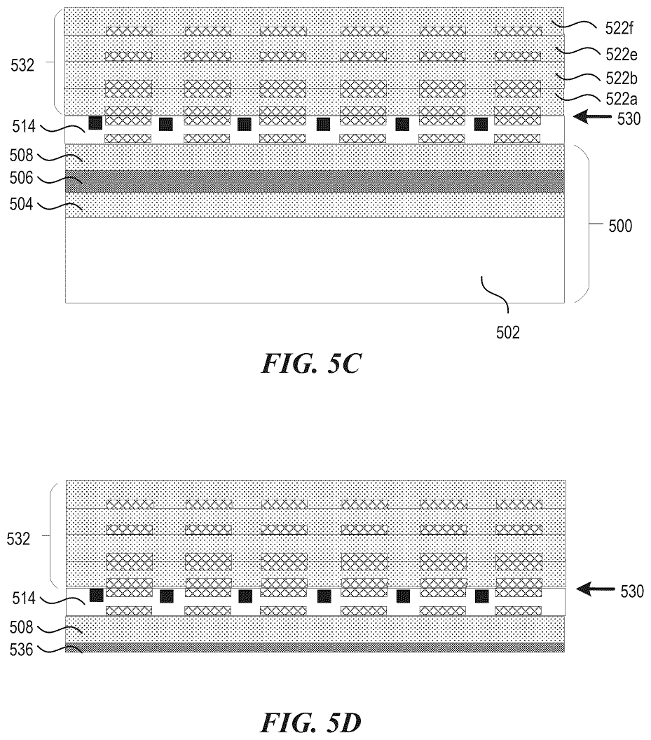

FIGS. 5A and 5B are schematic and cross-sectional side views of stacked semiconductor layers 522 that are F2F bonded to a semiconductor layer 514 having CMOS devices in accordance with various embodiments of the present technology. In this example, the stacked semiconductor layers 522 are bonded on the semiconductor layer 514 that is disposed above a carrier wafer 500. The carrier wafer includes a dielectric layer 508, a debond layer 506, and a dielectric layer 504 sequentially disposed above a substrate 502. In addition, each of the stacked semiconductor layers 522 include one or more memory arrays. Here, the stacking of the semiconductor memory wafers 522 above the semiconductor layer 514 can be conducted by repeating similar processes described in FIGS. 4D and 4E. For example, after bonding the most bottom semiconductor layer 522a on the semiconductor layer 514, similar to the process described in FIG. 4E, additional semiconductor wafers each having one or more memory arrays can be further stacked above the semiconductor layer 522a. For example, another semiconductor wafer including the semiconductor layer 522b can be bonded on the semiconductor layer 522b using a hybrid bonding technique, e.g., bonding the corresponding contact pads and dielectric layers at the interface between the semiconductor layers 522a and 522b. A substrate of the semiconductor wafer including the semiconductor layer 522b can be backside thinned using a CMP process, a back grinding process, or a wet or dry etching process. The backside thinning process exposes a backside surface of the semiconductor layer 522b, making it ready for bonding of additional semiconductor wafers having memory arrays. The bonding of semiconductor layers 522c and 522d can be similar to the semiconductor layer 522a and 522b, e.g., bonding the corresponding contact pads and dielectric layers at the interface between the semiconductor layers 522c and 522d. There are four memory array semiconductor layers that are stacked and bonded with the semiconductor layer 514 including CMOS devices as shown in FIG. 5A. In some other examples, the number of stacked semiconductor layers 522 can be 8, 12, 16, 20, 24, 28, 32, 64, 128, 256, and others.

The substrate 502 of the carrier wafer 500 can be further debonded from the bonding structure described in FIG. 5A. As shown in FIG. 5B, the substrate 502 can be deboned across the debond layer 506. Various semiconductor wafer debond processes can be adopted here to debond the substrate 502 from the bonding structure. For debond layer 506 that is made of metallic materials, a wafer debonding process such as chemical assisted debonding process or a mechanical debonding process can be conducted crossing the metal layer 506 of the carrier wafer 500 to debond the substrate 502 from the stacked semiconductor layers 522 and 514. In another example, for debond layer 506 that contains inert ions, a cleave process can be conducted, e.g., crossing a cleavage plane disposed in the debond layer 506, to debond the substrate 502. In this substrate debonding process, a mechanical or thermal stimulus can be applied to initiate the cleavage along the implanted cleavage plane of the debond layer 506 to separate the bulk substrate 502 from semiconductor layers 514 and 522 bonded there above. After the carrier wafer substrate is debonded, a residue debond layer 536 can be exist on a backside surface of the dielectric layer 508. In this example, the residue debond layer 536 contains materials, e.g., metallic material or inert ions, that are carried over from the debond layer 506.

In this example, the final semiconductor device assembly structure shown in FIG. 5B includes a stacked semiconductor layers 522 having memory arrays and a semiconductor layer 514 having CMOS devices. The frontside surface of the semiconductor layer 522a is faced towards to the frontside surface of the semiconductor layer 514, and forms a F2F bonding interface 530. In addition, the stacked semiconductor layers 522b, 522c, and 522d each having a frontside surface bonded to a backside surface of corresponding lower semiconductor layers of the stacked semiconductor layer 522, forming a plurality of F2B bonding interfaces therebetween. As shown in FIG. 5B, the F2B bonding interfaces among the semiconductor layers 522a-522d are hybrid bonding interfaces including bonded contact pads and dielectric layers. The semiconductor device assembly structure of FIG. 5B also includes the dielectric layer 508 and the residue debond layer 536 disposed on the backside surface of the semiconductor layer 514. In some examples, the residue debond layer 536 can be further removed using a wet or dry chemical etching process.

In some other examples, stacked semiconductor layers that has one surface only contains dielectric film can be F2F bonded to the semiconductor layer 514 having CMOS devices in accordance with various embodiments of the present technology. As shown in FIG. 5C, stacked semiconductor layers 532 are bonded on the semiconductor layer 514 that is disposed above the carrier wafer 500. Here, the stacking of the semiconductor memory wafers 532 above the semiconductor layer 514 can be conducted by repeating similar processes described in FIGS. 4D and 4E. For example, after bonding the most bottom semiconductor layer 522a on the semiconductor layer 514, similar to the process described in FIG. 4E, additional semiconductor wafers each having one or more memory arrays can be further stacked above the semiconductor layer 522a. For example, the semiconductor layer 522b can be bonded on the semiconductor layer 522a using a hybrid bonding technique, e.g., bonding the corresponding contact pads and dielectric layers at the interface between the semiconductor layers 522a and 522b. The substrate of the semiconductor wafer including the semiconductor layer 522b can be backside thinned using a CMP process, a back grinding process, or a wet or dry etching process. The backside thinning process exposes a backside surface of the semiconductor layer 522b, making it ready for bonding of additional semiconductor wafers having memory arrays. In this example, semiconductor layers 522e and 522f that only contain contact pads on the surface towards the substrate 502 can be bonded to and stacked above the semiconductor layer 522b, e.g., through dielectric-dielectric bonding.

In this example, the substrate 502 of the carrier wafer 500 can be further debonded from the bonding structure described in FIG. 5C. As shown in FIG. 5D, the substrate 502 can be deboned across the debond layer 506. After the carrier wafer substrate is debonded, a residue debond layer 536 can be exist on a backside surface of the dielectric layer 508. In this example, the final semiconductor device assembly structure shown in FIG. 5D includes a stacked semiconductor layers 532 having memory arrays and a semiconductor layer 514 having CMOS devices. The frontside surface of the semiconductor layer 522a is faced towards to the frontside surface of the semiconductor layer 514, and forms a F2F bonding interface 530. In addition, the stacked semiconductor layers 522b, 522e, and 522f each having a frontside surface bonded to a backside surface of corresponding lower semiconductor layers of the stacked semiconductor layer 522, forming a plurality of F2B bonding interfaces therebetween. As shown in FIG. 5D, the F2B bonding interfaces among the semiconductor layers 522a-522d can be hybrid bonding interfaces (e.g., on semiconductor layers 522a and 522b, including bonded contact pads and dielectric layers), and dielectric-dielectric bonding (e.g., on semiconductor layers 522e and 522f). The semiconductor device assembly structure of FIG. 5D also includes the dielectric layer 508 and the residue debond layer 536 disposed on the backside surface of the semiconductor layer 514.

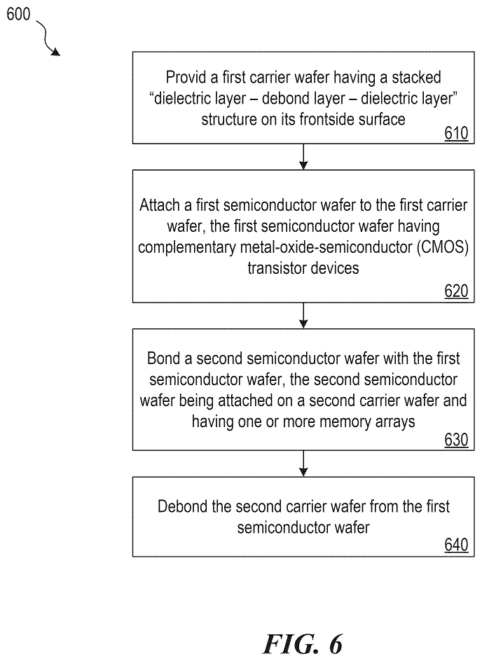

FIG. 6 shows a flow chart illustrating a method 600 for bonding and debonding semiconductor wafers in accordance with various embodiments of the present technology. The method 600 includes providing a first carrier wafer having a stacked “dielectric layer-debond layer-dielectric layer” structure on its frontside surface, at 610. For example, the carrier wafer 100 having the dielectric layer 104, debond layer 106, and dielectric layer 108 sequentially disposed above the frontside surface of the substrate 102, as shown in FIG. 1C, can be provided for the semiconductor wafer assembly process.

The method 600 also includes attaching a first semiconductor wafer to the first carrier wafer, the first semiconductor wafer having complementary metal-oxide-semiconductor (CMOS) transistor devices, at 620. For example, the semiconductor wafer 310 can be attached on the carrier wafer 300, through bonding a frontside surface of the semiconductor layer 314 of the semiconductor wafer 310 to the frontside surface of the dielectric layer 308, as shown in FIGS. 3B and 3C.

In addition, the method 600 includes bonding a second semiconductor wafer with the first semiconductor wafer, the second semiconductor wafer being attached on a second carrier wafer and having one or more memory arrays, at 630. For example, semiconductor wafer 320 including one or more memory arrays can be bonded with the semiconductor layer 314. As shown in FIGS. 3E and 3F, the frontside surface of the semiconductor layer 324 can be bonded to the backside surface of the semiconductor layer 314 to form the F2B bonding interface 330. In another example and as shown in FIGS. 4D and 4E, the semiconductor wafer 420 can be bonded on the semiconductor layer 414, having the frontside surface of semiconductor layer 424 bonded with the frontside surface of the semiconductor layer 414, to form a F2B bonding interface 430.

Lastly, the method 600 includes debonding the second carrier wafer from the first semiconductor wafer, at 640. For example, as shown in FIG. 3H, the substrate 302 can be debonded, alongside the dielectric layer 304 and across the debond layer 306. Various semiconductor wafer debonding techniques such as chemical assisted debonding process, mechanical debonding process, or cleave process can be used here to debond the substrate 302.

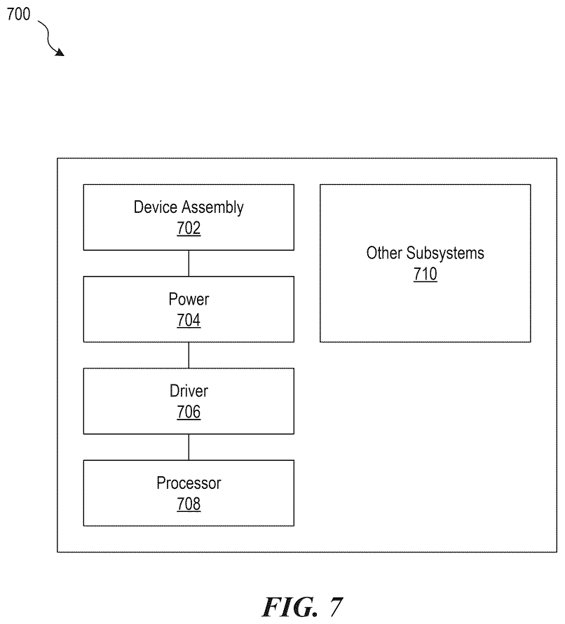

Any one of the semiconductor devices and semiconductor device assemblies described above with reference to FIGS. 1 to 6 can be incorporated into any of a myriad of larger and/or more complex systems, a representative example of which is system 700 shown schematically in FIG. 7. The system 700 can include a semiconductor device assembly (e.g., or a discrete semiconductor device) 702, a power source 704, a driver 706, a processor 708, and/or other subsystems or components 710. The semiconductor device assembly 702 can include features generally similar to those of the wafer bonding and debonding processes described above with reference to FIGS. 1 to 6. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 700 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor wafer having complementary metal-oxide-semiconductor (CMOS) transistor devices, the first semiconductor wafer having a first frontside surface and a first backside surface; and
a second semiconductor wafer having one or more memory arrays, the second semiconductor wafer having a second frontside surface and a second backside surface,
wherein a bonding interface is formed between the first backside surface of the first semiconductor wafer and the second frontside surface of the second semiconductor wafer, and
wherein the first semiconductor wafer has a first dielectric layer disposed on its first frontside surface.

2. The semiconductor device assembly of claim 1, further comprising a debond layer disposed on the first dielectric layer of the first semiconductor wafer.

3. The semiconductor device assembly of claim 2, further comprising a second dielectric layer disposed on the debond layer and a carrier wafer attached to the second dielectric layer, wherein the debond layer having a thickness up to 150 nm.

4. The semiconductor device assembly of claim 3, wherein the first dielectric layer and the second dielectric layer are made of materials including silicon oxide (SiO), silicon nitride (SIN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof.

5. The semiconductor device assembly of claim 2, wherein the debond layer is made of metallic materials including nickel, aluminum, titanium, copper, gold, and/or their alloy compound.

6. The semiconductor device assembly of claim 2, wherein the debond layer comprises inert ions.

7. The semiconductor device assembly of claim 1, further comprising inert ions on its second backside surface.

8. The semiconductor device assembly of claim 7, where in the inert ions comprise Hydrogen ion, Ar ion, Helium ion, Neon ion, Krypton ion, and/or Xenon ion.

9. The semiconductor device assembly of claim 1, wherein the bonding interface is a hybrid bonding interface or a fusion bonding interface.

10. A semiconductor device assembly, comprising:
a first semiconductor wafer having complementary metal-oxide-semiconductor (CMOS) transistor devices, the first semiconductor wafer having a first frontside surface and a first backside surface; and
a second semiconductor wafer having one or more memory arrays, the second semiconductor wafer having a second frontside surface and a second backside surface;
wherein a bonding interface is formed between the first frontside surface of the first semiconductor wafer and the second frontside surface of the second semiconductor wafer, and
wherein the first semiconductor wafer having a thickness ranging from 100 nm to 1 μm.

11. The semiconductor device assembly of claim 10, further comprising a dielectric layer disposed on the first backside surface of the first semiconductor wafer, and a debond layer disposed on the dielectric layer.

12. The semiconductor device assembly of claim 11, wherein the dielectric layer is made of materials including silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof.

13. The semiconductor device assembly of claim 11, wherein the debond layer is made of metallic materials including nickel, aluminum, titanium, copper, gold, and/or their alloy compounds.

14. The semiconductor device assembly of claim 11, wherein the debond layer comprises inert ions including Hydrogen ion, Ar ion, Helium ion, Neon ion, Krypton ion, and/or Xenon ion.

15. The semiconductor device assembly of claim 10, further comprising one or more semiconductor wafers stacked above the second semiconductor wafer, each of the one or more semiconductor wafers having one or more memory arrays.

16. A method of forming a semiconductor device assembly, comprising:
providing a first carrier wafer having a stacked “dielectric layer-debond layer-dielectric layer” structure on its frontside surface;
attaching a first semiconductor wafer to the first carrier wafer, the first semiconductor wafer having complementary metal-oxide-semiconductor (CMOS) transistor devices;
bonding a second semiconductor wafer with the first semiconductor wafer, the second semiconductor wafer being attached on a second carrier wafer and having one or more memory arrays; and
debonding the second carrier wafer from the first semiconductor wafer.

17. The method of claim 16, wherein the stacked “dielectric layer-debond layer-dielectric layer” structure of the first carrier wafer is formed by depositing a first dielectric layer, a debond layer, and a second dielectric layer sequentially on the frontside surface of the first carrier wafer.

18. The method of claim 16, wherein the stacked “dielectric layer-debond layer-dielectric layer” structure of the first carrier wafer if formed by depositing a dielectric layer on the frontside surface of the first carrier wafer and implanting inert ions into the dielectric layer.

19. The method of claim 16, wherein a frontside surface of the first semiconductor wafer is attached to the stacked “dielectric layer-debond layer-dielectric layer” structure of the first carrier wafer, and a frontside of the second semiconductor wafer is bonded to a backside surface of the first semiconductor wafer through a hybrid bonding interface or a fusion bonding interface.

20. The method of claim 16, wherein the CMOS transistor devices of the first semiconductor wafer is formed by depositing a silicon layer above the stacked “dielectric layer-debond layer-dielectric layer” structure of the first carrier wafer and fabricating CMOS transistor devices within the deposited silicon layer, and wherein a frontside of the second semiconductor wafer is bonded to a frontside surface of the first semiconductor wafer through a hybrid bonding interface or a fusion bonding interface.
